(19) United States
(12) Patent Application Publication
(10) Pub. No.: US 2012/0329233 A1
(43) Pub. Date: Dec. 27, 2012

(54) WAFER TREATMENT METHOD AND FABRICATING METHOD OF MOS TRANSISTOR

(76) Inventors: Ruei-Hao Huang, Hsinchu County (TW); Jung-Ching Chen, Hsinchu City (TW)

(21) Appl. No.: 13/169,032

(22) Filed: Jun. 27, 2011

(51) Int. Cl. H01L 21/336; B44C 1/22

(52) U.S. Cl. 438/301; 216/92; 216/83; 257/E21.409

(57) ABSTRACT

A wafer treatment method includes the following steps. A wafer is provided, wherein the wafer includes a substrate, a first oxide layer located on a front side of the substrate and a second oxide layer located on a back side of the substrate. An etching process is performed to entirely remove the first oxide layer. A fabricating method of a MOS transistor applying the wafer treatment method is also provided.

### BACKGROUND OF THE INVENTION

1. Field of the Invention

The present invention relates generally to a wafer treatment method and a fabricating method of a MOS transistor, and more specifically to a wafer treatment method and a fabricating method of a MOS transistor that only removes the oxide layer on the front side of the wafer or the MOS transistor.

2. Description of the Prior Art

In current semiconductor processes, a silicon nitride layer is formed on the back side of the wafer to prevent dopants in the wafer from coming out of the back side of the wafer during processing, as this causes pollution of the process ambient, thereby reducing process yields.

Although the addition of the silicon nitride layer can prevent the dopants in the wafer from coming out and also prevent the back side of the wafer from being etched, the wafer will be bent and distorted. The resultant non-flatness of the surface caused by the silicon nitride layer generates thermal stress and inner stress in the silicon wafer due to the difference in lattice size and lattice arrangement between the silicon nitride layer and the silicon wafer. As a result, the sequential lithography process will be misaligned, the yields of the wafer edge will be reduced, and various other problems will occur during processing, leading to defects existing in the eventual semiconductor devices.

### SUMMARY OF THE INVENTION

The present invention therefore provides a wafer treatment method and a fabricating method of a MOS transistor for solving the aforementioned problems.

The present invention provides a wafer treatment method that includes the following steps. A wafer is provided including a substrate, a first oxide layer located on a front side of the substrate and a second oxide layer located on a back side of the substrate. An etching process is performed to remove the entire first oxide layer.

The present invention provides a fabricating method of a MOS transistor including the following steps. A substrate is provided. An epitaxial process is performed to form an epitaxial layer on a front side of the substrate. An oxidation process is performed to respectively form an oxide layer on the epitaxial layer and on aback side of the substrate. A doping region is formed in the epitaxial layer. An etching process is performed to remove the oxide layer on the surface of the epitaxial layer.

According to the above, the present invention provides a wafer treatment method and a fabricating method of a MOS transistor, which only etches the oxide layer on the front side of the wafer and retains the oxide layer on the back side of the wafer. In this way, the oxide layer on the back side can be used as a stop layer and replaces the silicon nitride layer of the prior art for preventing dopants or impurities in the wafer from coming out and polluting the process ambient. Furthermore, by using an oxide layer as a stop layer, the problems of wafer bending or distortion caused by stress will not occur.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1-9 schematically depicts a cross-sectional view of a wafer treatment method according to one embodiment of the present invention.

FIG. 10 schematically depicts a cross-sectional view of a super junction MOS transistor according to one embodiment of the present invention.

### DETAILED DESCRIPTION

FIG. 1-9 schematically depicts a cross-sectional view of a wafer treatment method according to one embodiment of the present invention. Please refer to FIG. 1-9. As shown in FIG. 1, a wafer 100 is provided, wherein the wafer 100 includes a substrate 110, a first oxide layer 120 and a second oxide layer 130. The first oxide layer 120 is located on a front side S1 of the substrate 110 and the second oxide layer 130 is located on a back side S2 of the substrate 110. The substrate 110 may be a silicon substrate, a silicon containing substrate, or a silicon on insulator substrate. The first oxide layer 120 and the second oxide layer 130 may be a native oxide layer on the substrate 110, or an oxide layer formed by an oxidation process.

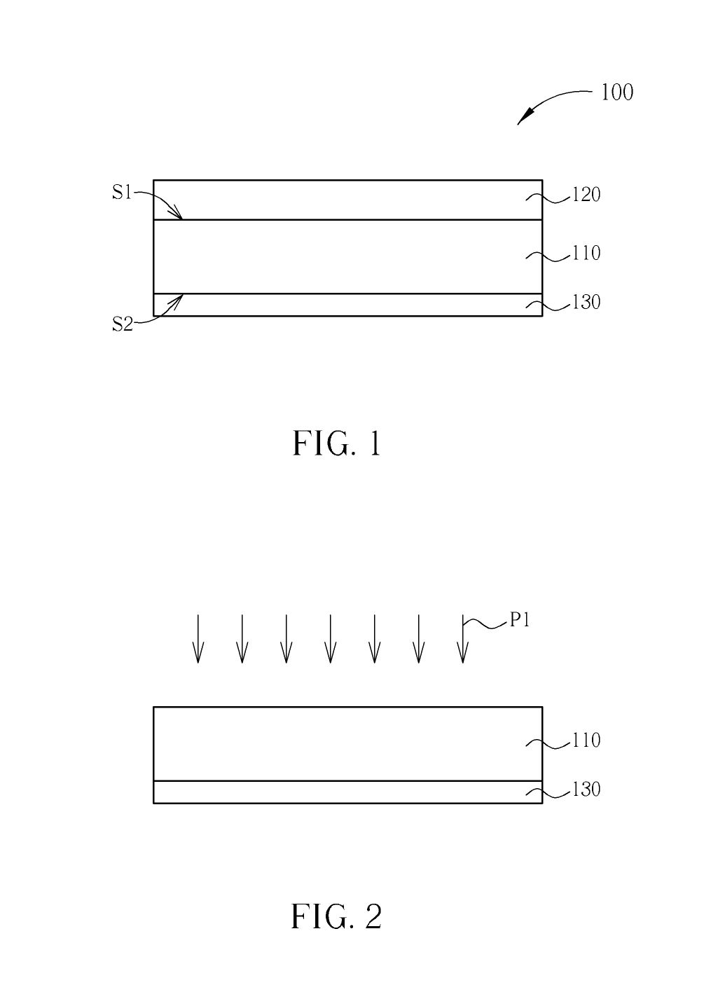

As shown in FIG. 2, an etching process P1 is performed to remove the entire first oxide layer 120. It is emphasized that only the first oxide layer 120 is removed in the present invention, meaning that the second oxide layer 130 is remained. That is, the present invention does not perform wet etching processes such as buffered oxide etch (BOE) process to etch the wafer 100, which soaks the wafer 100 in a wet bench directly, because the first oxide layer 120 and the second oxide layer 130 will be etched at the same time. In detail, if the second oxide layer 130 on the back side S2 is etched, the dopants or impurities such as antimony in the substrate 110 will come out of the substrate 110, leading to pollution of the process ambient. Moreover, when forming a nitride layer such as a silicon nitride layer to prevent pollution as in the prior art, the wafer 100 will be bended or distorted caused by stresses generated in the substrate 110 because of the difference in the materials of the substrate 110 and the nitride layer. Once the wafer 100 is distorted, negative effects such as misalignment of lithography processes, bad flatness of wafer, reduction of the yields of the wafer edge, or defects in the sequential processes will occur. Therefore, the present invention replaces the prior art nitride layer with the second oxide layer 130. Etching of only the first oxide layer 120 such that the second oxide layer 130 still remains means stresses in the substrate 110 will not be induced. Thus, not only can the coming out of dopants or impurities in the substrate 110 be avoided, but also the distortion of the wafer 100 can be averted. Moreover, the steps of forming the nitride layer are omitted and thereby the entire process is simplified.

In this embodiment, the etching process P1 etches a single wafer only once and the etching process P1 is a dynamic spin etching process. For example, the wafer 110 may be disposed on a base (not shown). An etchant maybe dropped on the front side of the wafer 110 and then the wafer 110 is rotated to remove the entire first oxide layer 120. It should be noted that this is merely one example and the present invention is not limited thereto.

Moreover, the thickness of the first oxide layer 120 and the second oxide layer 130 are generally greater than 2000 angstroms. In this embodiment, the thickness of the first oxide layer 120 is 3500 angstroms and the thickness of the second oxide layer 130 is 2000 angstroms. Taking the etching process P1 as a wet etching process for example, the etchant may include a hydrofluoric acid containing etchant for effectively etching that particular thickness of the first oxide layer 120. Specifically, the concentration of the hydrofluoric acid is 49%, which is higher than the concentration of the diluted hydrofluoric acid of the prior art, so that the first oxide layer 120 can be etched effectively. In one embodiment of the present invention, the etching process P1 can be performed by a SEZ machine, but it is also possible that other machines can be used to slightly etch the first oxide layer 120. Moreover, after the etching process P1 is performed, a cleaning process (not illustrated) is performed to clean the front side S1 of the substrate 110, wherein an ozonated DI water containing cleaning solution may be used in the cleaning process, but is not limited thereto.

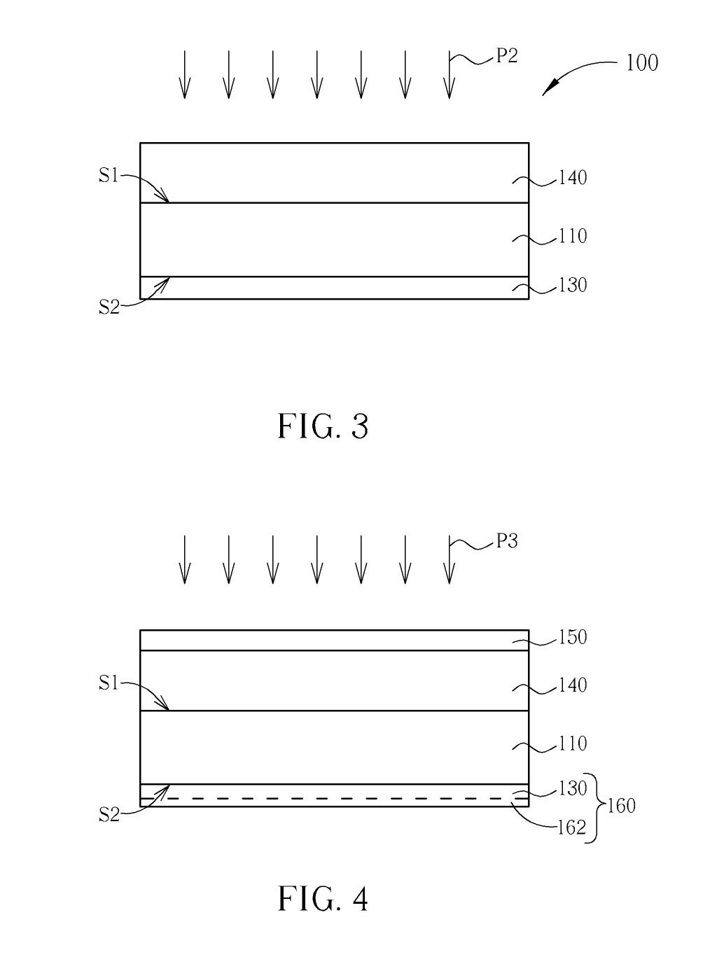

As shown in FIG. 3, after the etching process P1 is performed, an epitaxial process P2 is selectively performed to form an epitaxial layer 140 on the front side S1 of the substrate 110. The epitaxial process P2 may be an N-type silicon epitaxial process, a P-type silicon epitaxial process, a silicon germanium epitaxial process, or a silicon carbide epitaxial process; the type of process used depends upon the characteristic of the particular semiconductor device. In this embodiment, an N-type silicon epitaxial layer is formed on an N-type substrate.

As shown in FIG. 4, an oxidation process P3 may be performed to respectively form an oxide layer 150 on the front side S1 of the substrate 110 and form an oxide layer 160 on the back side S2 of the substrate 110, wherein the oxide layer 160 includes the second oxide layer 130 and the oxide layer 162 formed in the oxidation process P3. In other words, the second oxide layer 130 of the back side S2 can be thickened by performing the oxidation process P3. That is, the oxide layer 160 can be thickened while the oxide layer 150 is formed by the oxidation process P3, so that the capability of preventing impurities from coming out is intensified. The oxidation process P3 may be oxidation processes such as a rapid thermal oxidation process or an in situ steam generation (ISSG) oxidation process, which forms the oxide layers on the front side S1 and on the back side S2 simultaneously. Otherwise, an oxidation process which only forms one oxide layer on the front side S1 is also within the scope of the present invention, because the etching process P1 may just etch the oxide layer on the front side S1. Therefore, even if the oxide layer on the back side S2 will not be thickened in sequential processes, the objective of the present invention can still be achieved.

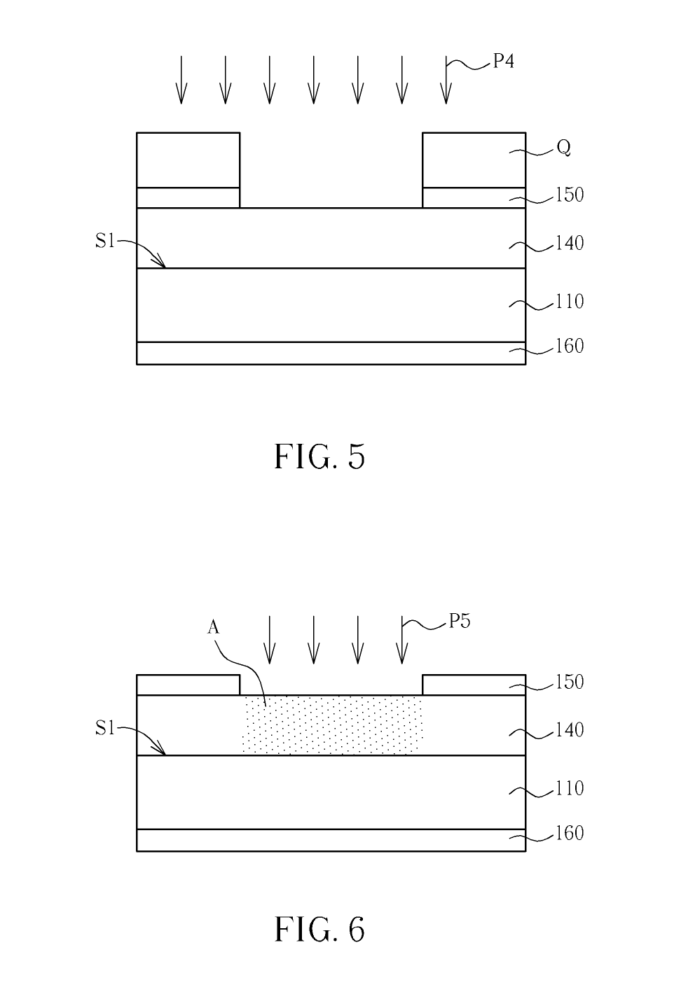

As shown in FIG. 5, after the oxidation process P3 is performed, an etching process P4 is further performed to remove at least a portion of the oxide layer 150 on the front side S1, wherein the oxide layer 150 can be entirely removed or patterned. If the oxide layer 150 is patterned by methods such as etching and lithography, a photoresist layer Q is formed on the oxide layer 150 first, the photoresist layer Q is subsequently patterned, and the pattern of the photoresist layer Q is then transferred to the oxide layer 150.

After the photoresist layer Q is removed, as shown in FIG. 6, an ion implantation process P5 is performed by using the patterned oxide layer 150 as a mask to form a doping region A in the epitaxial layer 140. The doping concentration, distribution and uniformity of the ion implantation process P5 can be adjusted by changing the pattern density of the oxide layer 150 or by using a half tone mask, which etches the upper portion of the oxide layer 150 and leaves a thinner oxide layer 150 to improve performance. Therefore, the doping region A can be formed in the epitaxial layer 140 via the steps illustrated in FIG. 5-6.

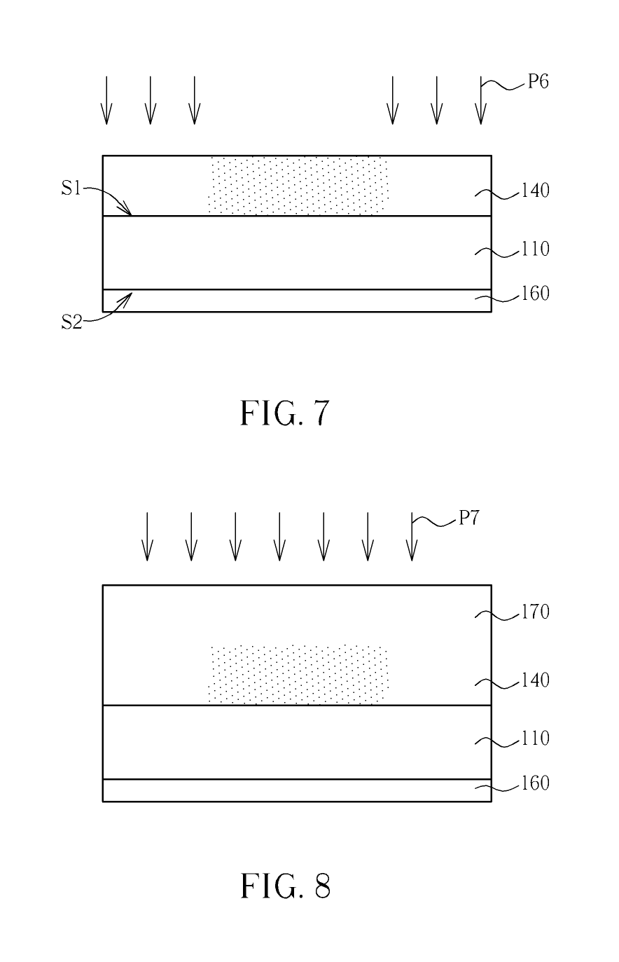

As shown in FIG. 7, an etching process P6 is performed to remove the oxide layer 150 remaining on the surface of the epitaxial layer 140. It is possible that the etching process P6 is the same as the etching process P1, which just etches the oxide layer 150 on the epitaxial layer 140 without etching the oxide layer 160 on the back side S2 of the substrate 110.

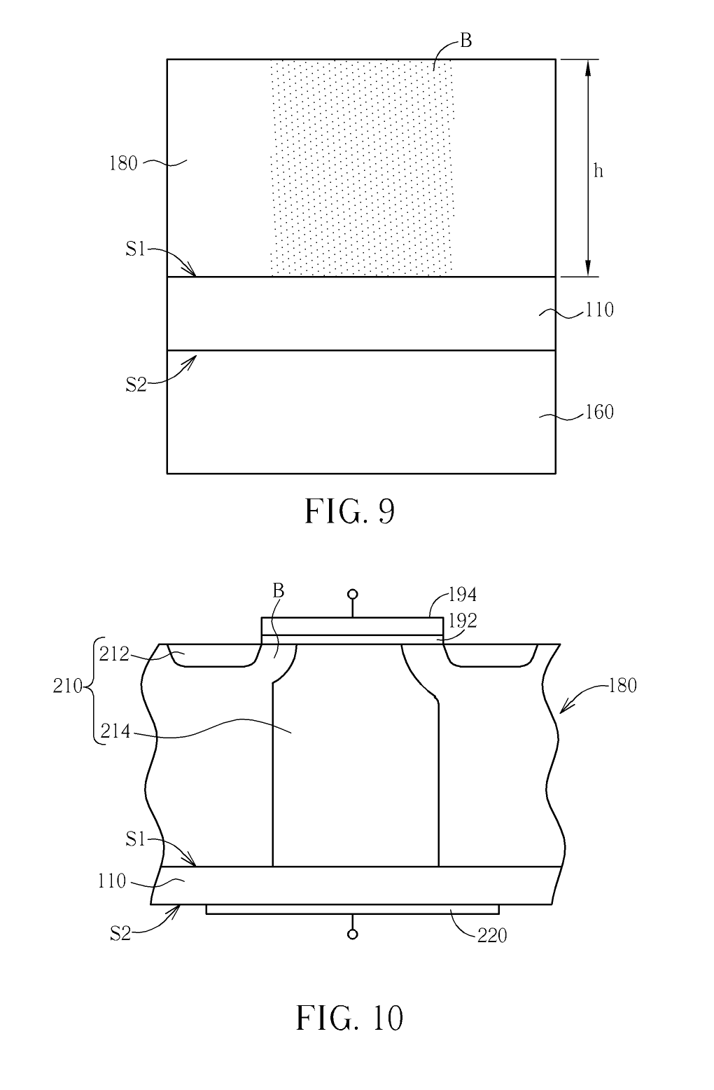

Additionally, due to the depth of the doping region in the epitaxial layer 140 formed each time the ion implantation process P5 is restricted, the thicker depth of the doping region A can be attained by performing the steps of FIG. 3-7 repeatedly. This thicker depth is often desired for manufacturing devices such as super-junction MOS transistors or high voltage semiconductor devices. For instance, as shown in FIG. 8, after the oxide layer 150 is removed, an epitaxial process P7 is further performed on the epitaxial layer 140 to form an epitaxial layer 170. That is, the thickness of the epitaxial layer can be thickened step by step. Then, a doping region (not shown), which extends the doping region A in the epitaxial layer 170, can be formed by sequentially performing the oxidation process, the patterned process, or the ion implantation process etc. as above. In doing so, a thicker epitaxial layer and doping region A can be formed. The aforementioned processes can be repeatedly performed, 5-8 times for example, depending upon the circumstances. Therefore, the structure shown in FIG. 9 can be formed. As shown in FIG. 9, the epitaxial layer 180 with a doping region B passing through it has a thickness h. The oxide layer 160 on the back side S2 is thickened by the repeatedly performed oxidation process without being affected by the etching process, which only removes the oxide layer 150 on the front side S1.

Finally, an oxide layer 160 can be selectively removed to further form other parts of the desired semiconductor devices. A super junction MOS transistor is shown in FIG. 10 as an example. FIG. 10 schematically depicts a cross-sectional view of a super junction MOS transistor according to one embodiment of the present invention. After the doping region B is formed, a dielectric layer (not shown) and an electrode layer (not shown) are sequentially formed and patterned to form at least a gate dielectric layer 192 and at least a gate electrode layer 194 respectively located on each gate dielectric layer 192. Then, an ion implantation process may be performed to form at least a source region 212, thereby forming a source/drain region 210 with the epitaxial layer 214 excluded from the doping region B. Thereafter, a spacer may be formed, an interlayer dielectric layer may be formed, or a metal inner connecting process may be performed. After the connecting process performed on the front side S1 is finished, the oxide layer 160 on the back side S2 is removed to expose the substrate 110. Then, a drain metal 220 on the back side S2 of the substrate 110 may be formed to complete the manufacturing of the MOS transistor. In one embodiment, the source/drain region 210 has a first conductive type (N-type for example), while the doping region B has a second conductive type (P-type for example), so that the doping region B can be a separate region.

Above all, the present invention provides a wafer treatment method and a fabricating method of a MOS transistor that only etches the oxide layer on the front side of the wafer and retains the oxide layer on the back side of the wafer. In doing so, the oxide layer gradually formed on the back side can be used as a stop layer and replaces the silicon nitride layer of the prior art to prevent dopants or impurities in the wafer from coming out and polluting the process ambient. By using the oxide layer as a stop layer, the problem of wafer bending or distortion caused by stresses will not occur. Therefore, the prior art problems of misalignment of processes, reduction of the wafer edge yields or defects can be avoided.

Those skilled in the art will readily observe that numerous modifications and alterations of the device and method may be made while retaining the teachings of the invention.

What is claimed is:

1. A wafer treatment method, comprising:
providing a wafer comprising a substrate, a first oxide layer located on a front side of the substrate and a second oxide layer located on a back side of the substrate; and
performing an etching process to remove the entire first oxide layer.

2. The wafer treatment method according to claim 1, wherein after performing the etching process, further comprising:
performing a plurality of oxidation processes repeatedly for further forming an oxide layer on the front side and the back side of the substrate wherein only the oxide layer on the front side is removed after every single oxidation process is performed.

3. The wafer treatment method according to claim 2, further comprising:
before performing the every single oxidation process, performing an epitaxial process to form an epitaxial layer on the front side.

4. The wafer treatment method according to claim 1, wherein the etching process etches a single wafer once.

5. The wafer treatment method according to claim 2, wherein the etching process is a dynamic spin etching process.

6. The wafer treatment method according to claim 1, wherein the etching process comprises etching by a hydrofluoric acid containing etchant and the concentration of the hydrofluoric acid is 49%.

7. The wafer treatment method according to claim 2, wherein the back side of the oxide layer is thickened each time an oxidation process is performed.

8. A fabricating method of a MOS transistor; comprising:
(a)providing a substrate;
(b)performing an epitaxial process to form an epitaxial layer on a front side of the substrate;
(c)performing an oxidation process to respectively form an oxide layer on the epitaxial layer and on a back side of the substrate;
(d)forming a doping region in the epitaxial layer; and
(e)performing an etching process to remove the oxide layer on the surface of the epitaxial layer.

9. The fabricating method of the MOS transistor according to claim 8, further comprising:
after performing the etching process to remove the oxide layer on the surface of the epitaxial layer, performing the steps of (b), (c), (d) and (e) repeatedly at least once.

10. The fabricating method of the MOS transistor according to claim 8, wherein the step of forming the doping region comprises:
performing an etching process to pattern the oxide layer on the epitaxial layer; and
performing an ion implantation process to form the doping region in the epitaxial layer.

11. The fabricating method of the MOS transistor according to claim 8, wherein the etching process comprises etching by a hydrofluoric acid containing etchant and the concentration of the hydrofluoric acid is 49%.

12. The fabricating method of the MOS transistor according to claim 8, wherein the etching process etches a single wafer once.

13. The fabricating method of the MOS transistor according to claim 8, wherein the etching process is a dynamic spin etching process.

14. The fabricating method of the MOS transistor according to claim 9, wherein the backside of the oxide layer is thickened each time an oxidation process is performed.

15. The fabricating method of the MOS transistor according to claim 9, further comprising:
after performing the etching process to remove the oxide layer on the surface of the epitaxial layer, forming at least a gate dielectric layer and at least a gate electrode layer; and
forming at least a source region to form a source/drain region with the epitaxial layer except for the doping region.

16. The fabricating method of the MOS transistor according to claim 15, further comprising:
after forming the source region, removing the oxide layer on the back side to expose the substrate; and
forming a drain metal on the back side of the substrate.

17. The fabricating method of the MOS transistor according to claim 16, wherein the source/drain region has a first conductive type while the doping region has a second conductive type.

18. The fabricating method of the MOS transistor according to claim 16, wherein the doping region is a separate region.
